(19) United States
(12) Patent Application Publication
(10) Pub. No.: US 2007/0024291 A1
(43) Pub. Date: Feb. 1, 2007

(54) Programmable pin electronics driver

(76) Inventor: Thomas W. Persons, Los Altos, CA (US)

Correspondence Address: FISH & RICHARDSON P.C., P.O. BOX 1022, MINNEAPOLIS, MN, 55440-1022, US

(21) Appl. No.: 11/193,035

(22) Filed: Jul. 29, 2005

(51) Int. Cl. G01R 27/08

(52) U.S. Cl. 324/713

(57) ABSTRACT

Apparatus that provides an output voltage to a device under test (DUT) includes a reference waveform generator to provide a waveform having a predefined swing, where the waveform is an analog signal that is based on data, a digital-to-analog converter (DAC) to receive the waveform, to scale the waveform using a scaling factor to produce a scaled waveform, and to generate a current that corresponds to the scaled waveform, and a resistive circuit connected to a circuit path that leads to the DUT. The current passing through the resistive circuit produces a voltage drop. The output voltage is based, at least in part, on the voltage drop.

### TECHNICAL FIELD

This patent application relates generally to a programmable pin electronic driver.

### BACKGROUND

Automatic test equipment (ATE) is typically an automated, usually computer-driven, apparatus for testing devices, such as semiconductors, electronic circuits, and printed circuit board assemblies. A device being tested by ATE is referred to as a device under test (DUT).

ATE outputs voltage signals to a DUT, and monitors reaction of the DUT to those signals. Different devices, however, require different voltage swings. For example, older devices use relatively large voltage swings, e.g., on the order of 0V to 5V. Newer devices, particularly those that support differential swings, require much smaller voltage swings. For example, some newer devices require 0.8V swings or even 0.2V swings.

ATE designed specifically for relatively large voltage swings has difficulty meeting the smaller voltage swing requirements of newer devices while still maintaining signal quality. That is, such ATE use relatively large transistors, which make it difficult to effect small voltage swings without adversely affecting signal quality. In this context, signal quality may be defined, e.g., in terms of numerous parameters, such as rise time, voltage overshoot or undershoot, settling time, and matching rise and fall times.

### SUMMARY

This application describes apparatus and methods, including computer program products, for implementing a programmable pin electronics driver that is configured to provide an output voltage to a DUT.

In general, in one aspect, the invention is directed to apparatus that provides an output voltage to a device under test (DUT). The apparatus includes a reference waveform generator to provide a waveform having a predefined swing, where the waveform includes an analog signal that is based on data, a digital-to-analog converter (DAC) to receive the waveform, to scale the waveform using a scaling factor to produce a scaled waveform, and to generate a current that corresponds to the scaled waveform, and a resistive circuit connected to a circuit path that leads to the DUT. The current passing through the resistive circuit produces a voltage drop. The output voltage is based, at least in part, on the voltage drop. This aspect may also include one or more of the following features.

The DAC may be programmable. The apparatus may include a processing device to provide the scaling factor to the DAC. A formatter may receive the data and may adjust a timing of the data so that the timing comports with timing requirements of the DUT.

The apparatus may include a vector memory to store the data, where the vector memory includes timing information along with the data, and a processing device to provide the timing requirements to the formatter. The formatter may alter the timing information so that the timing of the data comports with the timing requirements of the DUT. A voltage driver may provide at least one predefined voltage. The output voltage may also based on the predefined voltage. The output voltage may be based on a difference between the predefined voltage and the voltage drop. The predefined swing may account for losses caused on a circuit path to the DUT.

In general, in another aspect, the invention is directed to an apparatus that provides an output voltage to a DUT. The apparatus includes a DAC to receive a waveform having a predefined swing, to scale the waveform using a scaling factor to produce a scaled waveform, and to generate a current that corresponds to the scaled waveform. A resistive circuit is connected to a circuit path that leads to the DUT, the current passing through the resistive circuit producing a voltage drop. A voltage driver provides a predefined voltage. The output voltage is based on at least one of the predefined voltage and the voltage drop. This aspect may also include one or more of the following features.

A processing device may control the DAC so that the current is not generated. When the current is not generated, the output voltage may be based on the predefined voltage, but not the voltage drop. The voltage driver may be programmable to provide plural predefined voltages. The output voltage may be based on one of the plural predefined voltages. The DAC may be programmable. The apparatus may further include a processing device to provide the scaling factor to the DAC.

The apparatus may include a formatter to receive data and to adjust a timing of the data so that the timing comports with timing requirements of the DUT. The waveform may be based on the data. A vector memory may store the data, where the vector memory includes timing information along with the data. A processing device may provide the timing requirements to the formatter. The formatter may alter the timing information so that the timing of the data comports with the timing requirements of the DUT. Scaling the waveform using a scaling factor may include altering at least one of a swing of the waveform and an attenuation of the waveform.

In general, in another aspect, the invention is directed to a method of providing an output voltage to a DUT. The method includes generating a waveform having a predefined swing, and scaling the waveform to produce a scaled waveform, wherein scaling is performed using a digitally-programmed scaling factor to change the predefined swing, and wherein scaling results in an output current that corresponds to the scaled waveform. The method may also include generating the output voltage based on the output current. This aspect may also include one or more of the following features.

Generating the output voltage may include passing the current through a resistive circuit to produce a voltage drop, and reducing a predefined voltage by the voltage drop to produce the output voltage. The predefined voltage may be received from a voltage driver. The predefined voltage may be one of plural voltages available from the voltage driver.

The waveform may be generated to take into account losses that occur on a circuit path to the DUT. The method may further include receiving data from a memory, and changing a timing of the data to comport with a timing of the DUT. The waveform may be generated from data with changed timing. The waveform may be analog and scaling may be performed using a digital-to-analog converter (DAC).

The details of one or more examples are set forth in the accompanying drawings and the description below. Further features, aspects, and advantages of the invention will become apparent from the description, the drawings, and the claims.

### DESCRIPTION OF THE DRAWINGS

FIG. 1 is a block diagram of programmable pin electronic driver circuitry, which may be included in an ATE, for providing an output voltage to a DUT.

FIG. 2 is a flowchart of a process, which may be performed by the programmable pin electronic driver circuitry, for providing an output voltage to a DUT.

FIG. 3 is a flowchart of an alternative process, which may be performed by the programmable pin electronic driver circuitry, for providing an output voltage to a DUT.

Like reference numerals in different figures indicate like elements.

### DETAILED DESCRIPTION

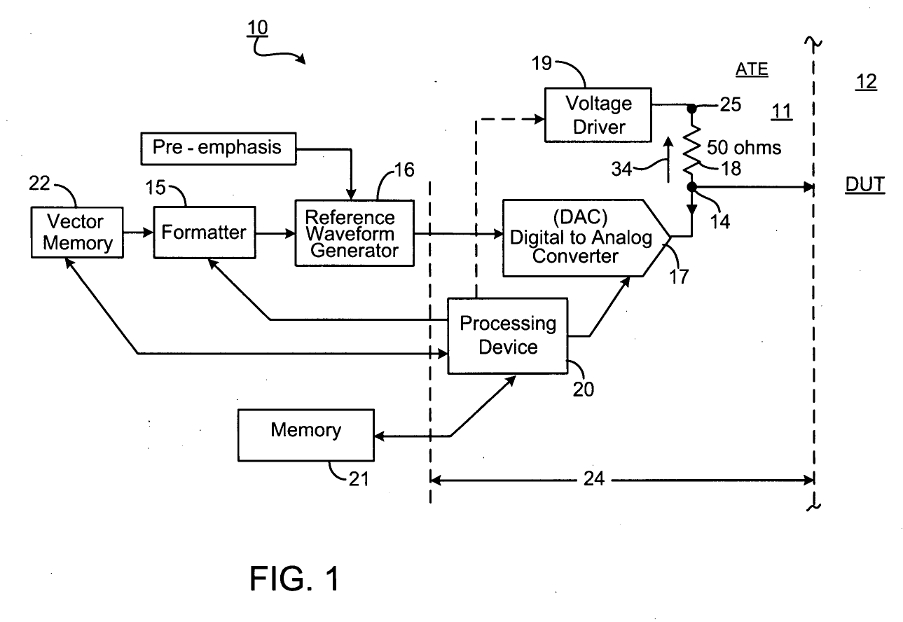

FIG. 1 is a block diagram of circuitry 10 in an ATE 11 for testing a DUT 12. Circuitry 10 is for use in providing, to DUT 12, an output voltage that comports with requirements of the DUT. In this regard, different DUTs may have different voltage swing requirements. Essentially, what this means is that different DUTs may recognize different voltage levels as “high” and “low” signals. For example, as noted in the Background section, older DUTs may recognize 0V and 5V as high and low voltages, whereas newer DUTs may recognize 0V and 0.8V as high and low voltages. As explained in detail below, circuitry 10 regulates the output voltage, namely the voltage at node 14, so that the output voltage comports with the requirements of DUT 12.

Circuitry 10 includes a formatter 15, a reference waveform generator 16, a digital-to-analog converter (DAC) 17, a resistive circuit 18 on a circuit path to the DUT, a voltage driver 19, and a processing device 20. Processing device 20 may be any type of digital device that is capable of executing instructions including, but not limited to, a microprocessor, a microcontroller, programmable logic such as an FPGA (field programmable gate array), and a digital signal processor (DSP). Processing device 20 may store its own instructions or retrieve them from an external source, such as memory 21. Processing device 20 executes instructions to performs functions in ATE 11.

Among the functions performed by processing device 20 in ATE 11 is control of DAC 17. Specifically, processing device 20 programs DAC 17 with a scaling factor that is used to scale an input waveform. What is meant by “scale”, in this context, is to affect the size and/or shape of the waveform in some manner. For example, DAC 17 may increase or decrease the magnitude and/or attenuation of the waveform. The scaling factor used by processing device 20 corresponds to the voltage requirements of DUT 12. That is, the scaling factor is selected so that the voltage at output node 14 meets the voltage swing requirements of DUT 12. DAC 17 is configured to accept digital programming data, making it possible to program the DAC relatively easily using processing device 20.

Formatter 15 receives data to be transferred to DUT 12 and adjusts the timing of the received data so that its timing comports with the requirements of DUT 12. The data may be of any type. For example, the data may be test data that is to be transferred from the ATE to the DUT in order to test aspects of the DUT. Alternatively, the data may be used to program the DUT for operation or for further testing.

Data to be transferred to the DUT may be stored in a memory, such as vector memory 22. Timing information may also be stored with the data. The timing information may indicate, e.g., temporal relationships among bits of the data. Processing device 20 transfers the data, and its timing information, from memory 22 to formatter 15. In formatter 15, the timing information is altered so that the timing of the data comports with timing requirements of DUT 12. Processing device 20 may program formatter 15 to comply with, or formatter 15 may be hard-coded with, timing requirements of DUT 12. For example, formatter 15 may be programmed to format the data so that the data is output as required by DUT 12, e.g., a bit may be output every 5 ns, 10 ns, etc.

Formatter 15 outputs appropriately-timed data to reference waveform generator 16. Reference waveform generator 16 generates a reference waveform having a predetermined swing for each bit of the data. More specifically, reference waveform generator 16 identifies bits in the data output by formatter 15, and substitutes predefined reference waveforms for those bits. The output of reference waveform generator 16 is thus an analog signal, which has the predefined voltage swing and the appropriate DUT timing.

Reference waveform generator 16 may also take into account losses that occur on circuit path 24 to DUT 12 when generating and applying the reference waveform. This is known as pre-emphasis. Pre-emphasis involves changing characteristics of a waveform, e.g., increasing its magnitude, in order to compensate for losses in a path to the DUT. Thus, when the waveform arrives at the DUT, as a result of the losses that occur on circuit path 24, the waveform will have the appropriate characteristics.

DAC 17 is a programmable analog-to-digital converter. In this implementation, DAC 17 is a multiplying-type converter, meaning that it scales an input signal by multiplying the signal by a scaling factor, and outputs a resulting scaled signal—in this case, a scaled voltage. DAC 17 receives the scaling factor from processing device 20, as noted above. During operation, DAC 17 outputs a current that corresponds to the scaled voltage. As described below, this current passes through resistive circuit 18 to generate a voltage drop 34 that contributes to the voltage output at node 14.

Resistive circuit 18 may include one or more resistive elements, e.g., resistors, configured in any arrangement, e.g., series, parallel, series and parallel, etc. (even though only one resistor is shown in FIG. 1). This implementation uses a resistive circuit having a resistance of 50Ω. Other implementations may use different resistances.

Voltage driver 19 may include a voltage source and circuitry for providing voltage from the voltage source to node 25. Voltage driver 19 may be programmable to output any voltage within a predefined range in response to a data signal. In other implementations, voltage driver 19 may be capable of outputting a limited number of discrete voltage levels in response to a data signal. For example, voltage driver 19 may respond to a data signal from processing device 20 to output only either a high voltage (Vih) or a low voltage (Vil). In other implementations, voltage driver 19 may be static, meaning that voltage driver is capable of outputting only a single voltage. As explained below, the output of voltage driver 19 may contribute to the output voltage at node 14.

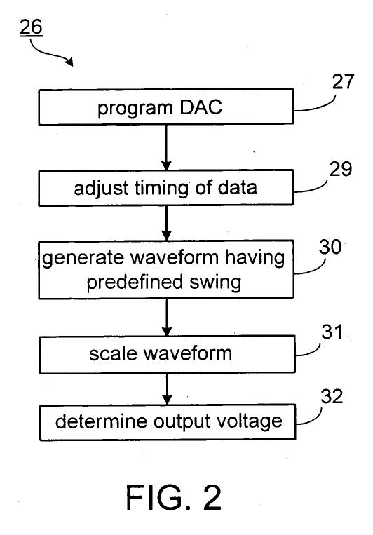

FIG. 2 is a flowchart showing a process 26, which may be implemented by circuitry 10, for providing a voltage output to DUT 12. According to process 26, processing device 20 programs (27) DAC 17 with a scaling factor that is appropriate for DUT 12. As explained above, the scaling factor will determine the voltage output of DAC 17, and thus the current output of DAC 17. Processing device may be programmed beforehand with the scaling factor, or processing device may query DUT 12 via other channels to obtain information required to determine the scaling factor. As noted above, in this implementation, the scaling factor is digital programming data.

In process 26, formatter 15 receives data from memory 22 and, along with the remainder of circuitry 10, generates voltage swings corresponding to that data for output to DUT 12. In particular, formatter 15 adjusts (29) a timing of the data so that the timing of the data comports with timing requirements of DUT 12. Reference waveform generator 16 generates (30) a waveform corresponding to the data output by formatter 15. In particular, reference waveform generator 16 generates a voltage swing for each bit of the data. The voltage swing has a predetermined magnitude and may, or may not, take pre-emphasis into account. Additionally, the voltage swing may, or may not, be a differential voltage swing.

DAC 17 receives, and scales (31), the voltage swing (i.e., waveform) output of reference waveform generator 16. Scaling the waveform in this manner is advantageous because it preserves characteristics of the waveform, such as matching rise and fall times, settling time, overshoot, undershoot, matching rise and fall propagation delays, and pre-emphasis. As indicated above, DAC 17 outputs a current that corresponds to the scaled waveform. The current output varies in accordance with characteristics of the voltage waveform. As a result, characteristics of the current substantially correspond to those of the waveform.

The current output of DAC 17 passes through resistive circuit 18. This results in a voltage drop 34 across resistive circuit 18. The amount of the voltage drop is controlled by controlling the current output. This voltage drop is used to determine (32) the output voltage at node 14. That is, the output voltage, in this implementation, is the difference between the voltage at node 25 (from voltage driver 19) and the voltage drop 34 across resistive circuit 18. The voltage at node 25 is reduced by voltage drop 34 to produce the voltage at node 14. As noted above, the output of voltage driver 19 may be static, meaning that voltage driver outputs a constant voltage, or the output may vary.

In alternative implementations, the resistance of resistive circuit 18 may be altered, either electronically or mechanically, which will effect the output voltage at node 14.

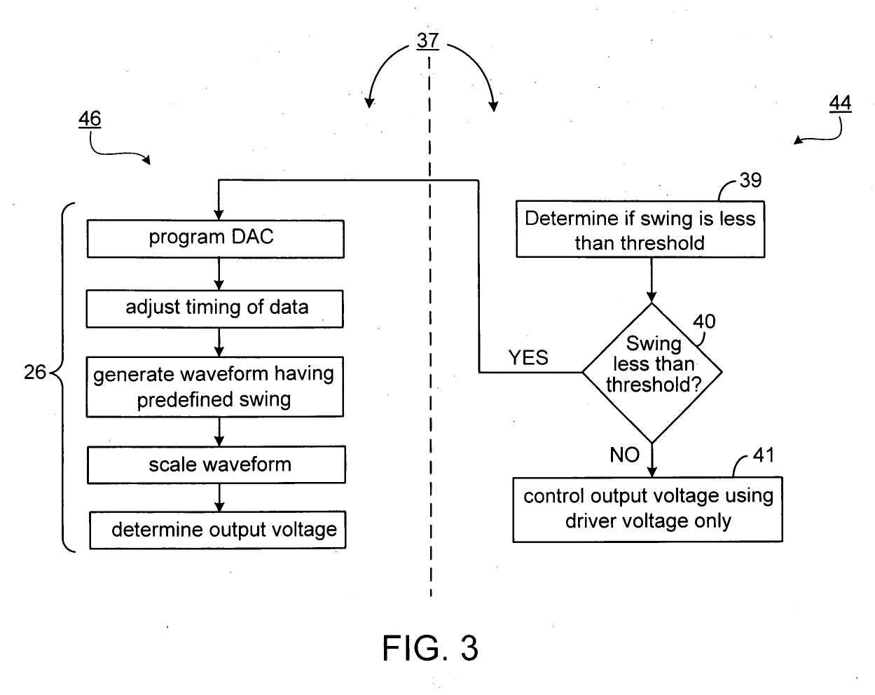

FIG. 3 shows an alternative process 37, which may be implemented by circuitry 10, for providing a voltage output to DUT 12. In this case, circuitry 10 uses a voltage driver that is programmable to output any voltage within a predefined range. It is noted that voltage driver 19 will have a limited resolution which may be, e.g., on the order of millivolts. This will, of course, limit the voltage levels that voltage driver 19 can output.

According to process 37, processing device 20 determines (39) whether a voltage swing required by DUT 12 is below a predefined threshold. For example, processing device 20 may query DUT 12 and determine if the voltage swing required by DUT 12 is less than, e.g., 0.1 V. If the voltage swing is greater than the predefined threshold (40), processing device 20 may use voltage driver 19 to control (41) the output voltage at node 14, but not DAC 17. In this case, processing device 20 deactivates DAC 17, or at least controls DAC 17 so that DAC 17 does not output current to resistive circuit 18. Because no current is output from DAC 17, the voltage at node 14 is substantially the same as the voltage at node 25 less, of course, any inherent voltage drops in the circuit path to node 14. This part 44 of process 37 can be used to provide relatively large voltage swings, e.g., on the order of volts, and is particularly useful for older types of DUTs.

Referring to FIG. 3, if the voltage swing is less than the predefined threshold (40), process 37 proceeds in accordance with process 26 (FIG. 2) to provide the output voltage at node 14 using the current output of DAC 17 and the voltage output of voltage driver 19. This part 46 of process 37 can be used to provide relatively small voltage swings, e.g., on the order of tenths of volts, and is particularly useful for newer types of DUTs.

The processes described herein are not limited to use with any particular hardware and software; they may find applicability in any computing or processing environment and with any type of machine that is capable of running machine-readable instructions. All or part of the processes can be implemented using digital electronic circuitry, or in computer hardware, firmware, software, or in combinations thereof.

All or part of the processes can be implemented as a computer program product, i.e., a computer program tangibly embodied in an information carrier, e.g., in a machine-readable storage device or in a propagated signal, for execution by, or to control the operation of, data processing apparatus, e.g., a programmable processor, a computer, or multiple computers. A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a communication network.

One or more actions or tasks associated with the processes can be performed by one or more programmable processors executing one or more computer programs to perform the functions of the processes. The actions or tasks can also be performed by, and the processes can be implemented as, special purpose logic circuitry, e.g., an FPGA and/or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer include a processor for executing instructions and one or more storage area devices for storing instructions and data. Generally, a computer will also include, or be operatively coupled to receive data from, or transfer data to, or both, one or more mass storage devices for storing data, e.g., magnetic, magneto-optical disks, or optical disks. Information carriers suitable for embodying computer program instructions and data include all forms of non-volatile storage area, including by way of example, semiconductor storage area devices, e.g., EPROM, EEPROM, and flash storage area devices; magnetic disks, e.g., internal hard disks or removable disks; magneto-optical disks; and CD-ROM and DVD-ROM disks.

All or part of the processes can be implemented in a computing system that includes a back-end component, e.g., as a data server, or that includes a middleware component, e.g., an application server, or that includes a front-end component, e.g., a client computer having a graphical user interface, or any combination of such back-end, middleware, or front-end components. The components of the system can be interconnected by any form or medium of digital data communication, e.g., a communication network. Examples of communication networks include a LAN and a WAN, e.g., the Internet.

Actions or tasks associated with the processes can be rearranged and/or one or more such steps can be omitted to achieve the same, or similar, results to those described herein.

Elements of different implementations described herein may be combined to form other implementations not specifically set forth above. Other implementations not specifically described herein are also within the scope of the following claims.

1. An apparatus to provide an output voltage to a device under test (DUT), the apparatus comprising:
a reference waveform generator to provide a waveform having a predefined swing, the waveform comprising an analog signal that is based on data;
a digital-to-analog converter (DAC) to receive the waveform, to scale the waveform using a scaling factor to produce a scaled waveform, and to generate a current that corresponds to the scaled waveform; and
a resistive circuit connected in a circuit path that leads to the DUT, the current passing through the resistive circuit to produce a voltage drop, wherein the output voltage is based, at least in part, on the voltage drop.

2. The apparatus of claim 1, wherein the DAC is programmable; and
wherein the apparatus further comprises a processing device to provide the scaling factor to the DAC.

3. The apparatus of claim 1, further comprising:
a formatter to receive the data and to adjust a timing of the data so that the timing comports with timing requirements of the DUT.

4. The apparatus of claim 3, further comprising:
a vector memory to store the data, the vector memory including timing information along with the data; and
a processing device to provide the timing requirements to the formatter;
wherein the formatter alters the timing information so that the timing of the data comports with the timing requirements of the DUT.

5. The apparatus of claim 1, further comprising:
a voltage driver to provide at least one predefined voltage;
wherein the output voltage is also based on the predefined voltage.

6. The apparatus of claim 5, wherein the output voltage is based on a difference between the predefined voltage and the voltage drop.

7. The apparatus of claim 1, wherein the predefined swing accounts for losses caused on a circuit path to the DUT.

8. An apparatus to provide an output voltage to a device under test (DUT), the apparatus comprising:
a digital-to-analog converter (DAC) to receive a waveform having a predefined swing, to scale the waveform using a scaling factor to produce a scaled waveform, and to generate a current that corresponds to the scaled waveform;
a resistive circuit connected in a circuit path that leads to the DUT, the current passing through the resistive circuit to produce a voltage drop; and
a voltage driver to provide a predefined voltage, the output voltage being based on at least one of the predefined voltage and the voltage drop.

9. The apparatus of claim 8, further comprising:
a processing device to control the DAC so that the current is not generated;
wherein, when the current is not generated, the output voltage is based on the predefined voltage, but not the voltage drop.

10. The apparatus of claim 8, wherein the voltage driver is programmable to provide plural predefined voltages, the output voltage being based on one of the plural predefined voltages.

11. The apparatus of claim 8, wherein the DAC is programmable; and
wherein the apparatus further comprises a processing device to provide the scaling factor to the DAC.

12. The apparatus of claim 8, further comprising:
a formatter to receive data and to adjust a timing of the data so that the timing comports with timing requirements of the DUT;
wherein the waveform is based on the data.

13. The apparatus of claim 12, further comprising:
a vector memory to store the data, the vector memory including timing information along with the data; and
a processing device to provide the timing requirements to the formatter;
wherein the formatter alters the timing information so that the timing of the data comports with the timing requirements of the DUT.

14. The apparatus of claim 8, wherein scaling comprises altering at least one of a swing of the waveform and an attenuation of the waveform.

15. A method of providing an output voltage to a device under test (DUT), the method comprising:
generating a waveform having a predefined swing;
scaling the waveform to produce a scaled waveform, wherein scaling is performed using a digitally-programmed scaling factor to change the predefined swing, and wherein scaling results in an output current that corresponds to the scaled waveform;
passing the output current through a resistive circuit to produce a voltage drop;
reducing a predefined voltage by the voltage drop to produce the output voltage; and
providing the output voltage to the DUT.

16. (canceled)

17. The method of claim 15, further comprising:
receiving the predefined voltage from a voltage driver, the predefined voltage comprising one of plural voltages available from the voltage driver.

18. The method of claim 15, wherein the waveform is generated to take into account losses that occur on a circuit path to the DUT.

19. The method of claim 15, further comprising:
receiving data from a memory; and
changing a timing of the data to comport with a timing of the DUT;
wherein the waveform is generated from data with changed timing.

20. The method of claim 15, wherein the waveform is analog and scaling is performed using a digital-to-analog converter (DAC).
